(19) United States
(12) Patent Application Publication
(10) Pub. No.: US 2024/0428393 A1
(43) Pub. Date: Dec. 26, 2024

(54) CUTTING PATH PLANNING ALGORITHM FOR SEMICONDUCTOR WORKPIECE BASED ON IMAGE PROCESSING

(71) Applicant: Taiyuan University of Science and Technology, Taiyuan City (CN)

(72) Inventors: Anhong WANG, Taiyuan City (CN); Hao JING, Taiyuan City (CN); Zishan TANG, Taiyuan City (CN); Peihao LI, Taiyuan City (CN); Jiapeng JIA, Taiyuan City (CN)

(21) Appl. No.: 18/736,759

(22) Filed: Jun. 7, 2024

(30) Foreign Application Priority Data
Jun. 25, 2023 (CN) 202310751582.6

(51) Int. Cl. G06T 7/00; G06F 30/392; G06T 7/11; G06T 7/12; G06T 7/136

(52) U.S. Cl. CPC G06T 7/0004; G06F 30/392; G06T 7/11; G06T 7/12; G06T 7/136; G06T 2207/20081; G06T 2207/30148; G06T 2207/30164

(57) ABSTRACT

Disclosed is a cutting path planning algorithm for semiconductor workpiece based on image processing, belonging to the technical field of image calculation, and solving the technical problem of manually cutting off the heterocrystal region on the wafer, which includes the following steps: 1, obtaining a semantic boundary of an image; 2, finding a largest inscribed rectangle MRect in the single crystal image X₁; 3. dividing the contour region in the single crystal region to find the corresponding cutting line; 4. determining the final cutting line. The cutting line planned by the application may realize automatic cutting of the wafer, and may better reserve the required single crystal region.

### CROSS-REFERENCE TO RELATED APPLICATIONS

This application claims priority to Chinese Patent Application No. 202310751582.6, filed on Jun. 25, 2023, the contents of which are hereby incorporated by reference.

### TECHNICAL FIELD

The application belongs to the technical field of image calculation, and in particular relates to a cutting path planning algorithm for semiconductor workpiece based on image processing.

### BACKGROUND

A clean single crystal wafer is required for the growth of epitaxial layers of semiconductor materials. However, when the semiconductor material is cut from a crystal rod into wafers, there will be many different crystalline phases on each wafer, and it is necessary to remove the heterocrystal regions on the wafer and retain the required single crystal part.

In the prior art, the process flow of semiconductor wafer cutting is as follows: after the semiconductor material is cut into wafers from crystal rods, the boundaries between single crystals and heterocrystals are identified manually, and then the clean single crystal wafers are obtained by manual cutting with a knife. Most semiconductor materials contain precious and heavy metals with high value, and the existing manual processing methods will waste a lot of human resources; moreover, when cutting the wafer, manual instability often causes cutting errors or damage to the wafers, resulting in material waste; in addition, heavy metal materials are easily inhaled during manual operation, which will cause harm to operators.

### SUMMARY

The main objective of the application is to overcome the shortcomings in the prior art and solve the technical problem of manually cutting off the heterocrystal region on the wafer. The application provides a cutting path planning algorithm for semiconductor workpiece based on image processing.

The design concept of the application is as follows:
when cutting a wide-bandgap semiconductor material, it is necessary to keep the required single crystal part on a wafer with various crystal phases, so it is necessary to plan the cutting path to ensure that the usable part on the wafer is capable of being used to the maximum extent. According to the position of the single crystal on the wafer, the application uses an image processing algorithm to plan the cutting path to achieve the objective of automatic cutting. The algorithm proposed by the application firstly finds the largest inscribed rectangle in the single crystal contour, and then plans the path according to the intersection of the inscribed rectangle and the single crystal contour. Specifically, the algorithm includes the following steps: obtaining and preprocessing the workpiece image→extracting the single crystal contour→finding the largest inscribed rectangle→planning the cutting path.

The application is realized by the following technical scheme: a cutting path planning algorithm for semiconductor workpiece based on image processing, including the following steps:
S1, obtaining a semantic boundary of an image:
S1-1, obtaining a semantic image X through a deep learning model, and distinguishing different crystal phase regions in a wafer according to the semantic image X, where crystal phase regions to be reserved are single crystal regions, and a rest part are heterocrystal regions; setting the semantic image X as a gray scale map, where gray scale values of the single crystal regions are different from gray scale values of the heterocrystal regions;
S1-2, adjusting a color of the heterocrystal regions in the semantic image X obtained in S1-1 to be same as a background color to obtain a single crystal image X₁;
S2, finding a largest inscribed rectangle MRect in the single crystal image X₁:
S2-1, finding all contours in the single crystal image X₁, taking a contour with a largest area as a machining contour of a required product, and recording as contour “contour”, and then storing all contour points on the contour “contour” in sequence, and making a position difference between two adjacent contour points not greater than 1;
S2-2, randomly selecting a contour point on the contour “contour” and marking the contour point as start(x,y), circulating points in the contour “contour” with the start(x,y) as a starting point, marking a current point on the contour “contour” as cur(x,y), and taking the starting point start(x, y) and the current point cur(x,y) as diagonal points of the rectangle to construct a rectangular contour;
S2-3, judging whether the rectangular contour constructed in S2-2 are all located inside the contour “contour”, and if the rectangular contour constructed in S2-2 are all located inside the contour “contour”, recording an area of the rectangular contour and corresponding diagonal point coordinates in this state;
S2-4, repeatedly executing steps S2-2 to S2-3, traversing all points on the contour “contour” to obtain an inscribed rectangular contour maxRect with a largest area in the contour “contour”, and recording coordinates and an area of the inscribed rectangular contour maxRect with the largest area;
S2-5, calculating a space moment mⱼᵢ of the contour “contour” according a formula (1):

$${m}_{ji} = {\sum }_{x , y} ( ( x , y ) * {x}^{j} * {y}^{i} ) ; \qquad ( 1 )$$

in the formula (1), x and y are coordinate values of the contour “contour”, and i and j are image orders;
S2-6, when the image order i=0 or 1, and j=0 or 1, calculating a centroid center(x, y) of the contour “contour” from moo, mw and mol obtained by a formula (2):

$$\{ \begin{matrix}x = \frac{{m}_{10}}{{m}_{00}} \\ y = \frac{{m}_{01}}{{m}_{00}}\end{matrix} ; \qquad ( 2 )$$

S2-7, rotating the single crystal image X₁ with the centroid center(x, y) of the contour “contour” determined in the S2-6 as a center, and obtaining a single crystal image Xᵢ every 5° of a rotation, wherein i is an integer greater than 1, and rotating by 360° in total, and repeating operations in the S2-2 to the S2-6 in each single crystal image Xᵢ to obtain all contours “contour” of each single crystal image Xᵢ;
S2-8, comparing the inscribed rectangular contour maxRect with the largest area among all the contours “contour” in each single crystal image Xᵢ, and determining an inscribed rectangle with a largest area in the single crystal region as MRect;
S3, dividing contour regions in the single crystal regions to find corresponding cutting lines:
S3-1, respectively extending one side of four sides of the inscribed rectangle MRect to an outside, and dividing the single crystal regions outside the inscribed rectangle MRect into four regions of Con₁, Con₂, Con₃ and Con₄ by two extension lines at each vertex position of the inscribed rectangle MRect;
S3-2, selecting an intersection point of a vertex or the extension line of the inscribed rectangle MRect in Con₁ region and a contour of the single crystal region as P₁(x,y), forming a straight line with any point P₂(x,y) in the Con₁ region, circulating all points in the Con₁ region, calculating an area of a straight line formed by P₂(x,y) and P₁(x,y) cutting off heterocrystal regions, and sorting according to sizes of cutting off areas of the heterocrystal regions; selecting a group with a largest cutting off area of the heterocrystal regions as a candidate cutting line L₁; if areas of the heterocrystal regions cut off are the same, selecting a group with a largest area of a reserved single crystal region as the candidate cutting line L₁;
in Con₁, selecting an intersection point of an another vertex or extension line of the inscribed rectangle MRect and a contour of the single crystal region as P₃(x,y), forming a straight line with any point P₂(x,y) in the Con₁ region, and circulating all points in the Con₁ region, and calculating an area of a straight line formed by P₂(x,y) and P₃(x,y) cutting off heterocrystal regions, and determining the candidate cutting line L₂ in a same way as in the S3-2;
similarly, obtaining corresponding candidate cutting lines L₃, L₄, L₅ and L₆ in Con₂ region, Con₃ region and Cor₄ region respectively;
S4, determining a final cutting line:
traversing six candidate cutting lines L₁, L₂, L₃, L₄, L₅ and L determined in the S3, and selecting a path being capable of forming a convex polygon single crystal region with a largest area, a largest area of the heterocrystal region cut off and a least number of straight line cutting off as a final cutting line path; a path optimization method is as follows:
setting an area of a divided single crystal pixel region to be Sₓ, A(⋅) represents an area of the single crystal region cut off and Z(⋅) represents an area of the heterocrystal region cut off:

$${r}_{opt 1} = ( {arg max}_{{r}_{e} , e ∈ Φ} ( {S}_{x} - A ( {arg max}_{{r}_{e} , e ∈ Φ} ( Z ( {r}_{e} {⋃}_{k = 1}^{p} {l}_{k} ) ) ) ) ) {\vert}_{min p} ; \qquad ( 3 )$$

$$Φ = [ 1 , {\sum }_{p = 1}^{m} {C}_{m}^{p} ] , {shape}_{e} is convex ; \qquad ( 4 )$$

where p represents a number of currently selected cutting lines; lₖ represents a selected k-th cutting line; m represents a total number of all candidate cutting lines, meaning a maximum number, Cₘ^{p} represents a number of permutation and combinations of selected p cutting lines among all m cutting lines; rₑ represents a planned path under a current e-th permutation and combination; shapeₑ represents a shape of a wafer cut by an e-th path; Φ represents a value range of e; rₒₚₜ₁ represents a currently selected optimal path, including selected p cutting lines.

Compared with the prior art, the application has the following beneficial effects.

The application provides a cutting path planning algorithm for semiconductor workpiece based on image processing, which realizes the automation of marking path planning, and the planned path may realize the marking of wafers, and meets the actual processing requirements while the number of cutting knives is small. The single crystal obtained as a result of cutting does not include heterocrystals, and the integrity of heterocrystals may be ensured while the single crystal part is reserved to the maximum extent, so that the waste of materials is reduced, and the processing efficiency of wafer scribing is improved. Compared with the existing manual cutting-up, the application may avoid the damage to the wafer caused by manual dicing and the harm to the human body caused by long-term contact with the wafer during processing.

### BRIEF DESCRIPTION OF THE DRAWINGS

FIG. 1 is a flow chart of the present application.

FIG. 2 is a crystal diagram of a semantic image X obtained by a deep learning model in a specific embodiment.

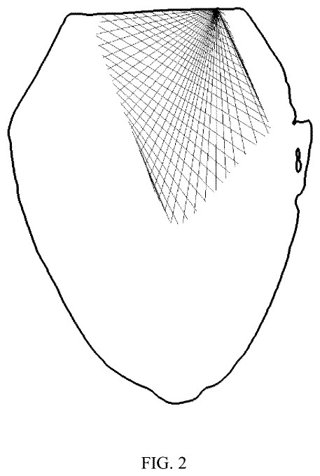

FIG. 3 is a crystal diagram of the single crystal region obtained after the preprocessing of FIG. 2 (the color of the heterocrystal region is adjusted to be same as the background color).

FIG. 4 is a crystal diagram of a single crystal region obtained after the rotation of FIG. 3.

FIG. 5 is a schematic diagram of a contour region in a single crystal region.

FIG. 6 is a schematic diagram of a candidate cutting line.

FIG. 7 is a cutting path diagram in a specific embodiment.

### DETAILED DESCRIPTION OF THE EMBODIMENTS

In the following, the application will be further described in detail with the attached drawings and embodiments.

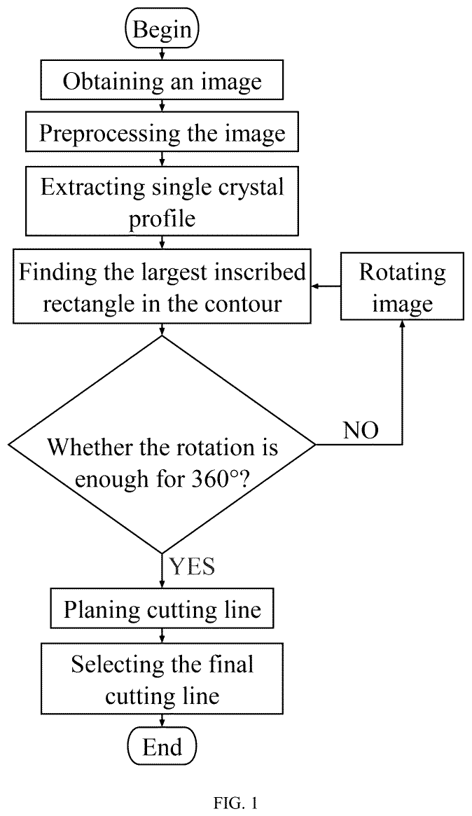

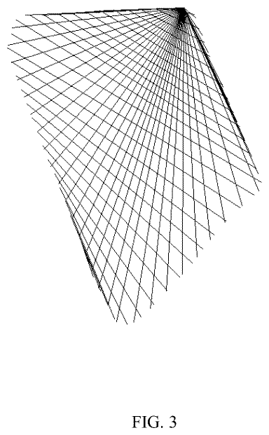

As shown in FIG. 1, a cutting path planning algorithm for semiconductor workpiece based on image processing includes the following steps:
S1, obtaining a semantic boundary of an image:
S1-1, obtaining a semantic image X through a deep learning model, and distinguishing different crystal phase regions in a wafer according to the semantic image X, wherein crystal phase regions to be reserved are single crystal regions, and a rest part are heterocrystal regions; setting the semantic image X as a gray scale map, where gray scale values of the single crystal regions are different from gray scale values of the heterocrystal regions. In this embodiment, the grayscale value of the single crystal region is 50, and the grayscale value of the heterocrystal region is 100.
S1-2, adjusting a color of the heterocrystal regions in the semantic image X obtained in S1-1 to be same as a background color to obtain a single crystal image X₁ (as shown in FIG. 3);
S2, finding a largest inscribed rectangle MRect in the single crystal image X₁;
S2-1, finding all contours in the single crystal image X₁, taking a contour with a largest area as a machining contour of a required product, and recording as contour “contour”, and then storing all contour points on the contour “contour” in sequence, and making a position difference between two adjacent contour points not greater than 1;
S2-2, randomly selecting a contour point on the contour “contour” and marking the contour point as start(x,y), circulating points in the contour “contour” with the start(x,y) as a starting point, marking a current point on the contour “contour” as cur(x,y), and taking the starting point start(x, y) and the current point cur(x,y) as diagonal points of the rectangle to construct a rectangular contour;
S2-3, judging whether the rectangular contour constructed in S2-2 are all located inside the contour “contour”, and if the rectangular contour constructed in S2-2 are all located inside the contour “contour”, recording an area of the rectangular contour and corresponding diagonal point coordinates in this state;
S2-4, repeatedly executing steps S2-2 to S2-3, traversing all points on the contour “contour” to obtain an inscribed rectangular contour maxRect with a largest area in the contour “contour”, and recording coordinates and an area of the inscribed rectangular contour maxRect with the largest area;
S2-5, calculating a space moment mji of the contour “contour” according a formula (1):

$${m}_{ji} = {\sum }_{x , y} ( ( x , y ) * {x}^{j} * {y}^{i} ) ; \qquad ( 1 )$$

In the formula (1), x and y are coordinate values of the contour “contour”, and i and j are image orders;
S2-6, when the image order i=0 or 1, and j=0 or 1, calculating a centroid center(x, y) of the contour “contour” from m00, m10 and m01 obtained by a formula (2):

$$\{ \begin{matrix}x = \frac{{m}_{10}}{{m}_{00}} \\ y = \frac{{m}_{01}}{{m}_{00}}\end{matrix} ; \qquad ( 2 )$$

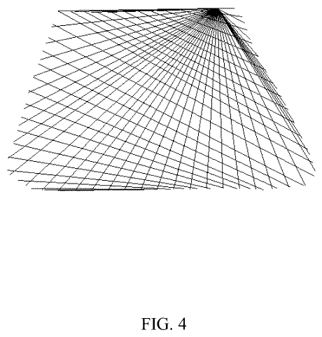

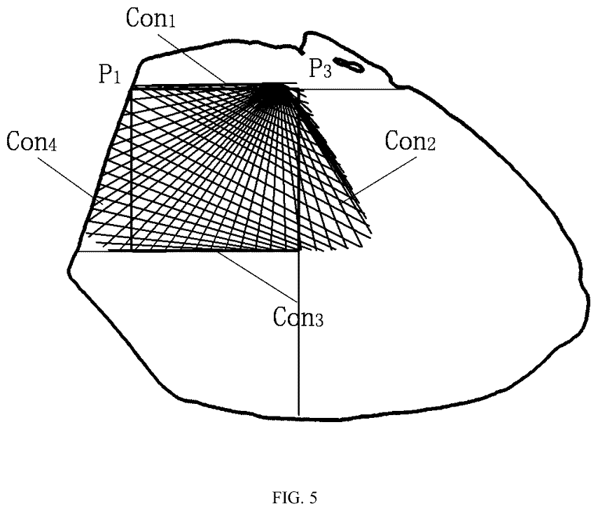

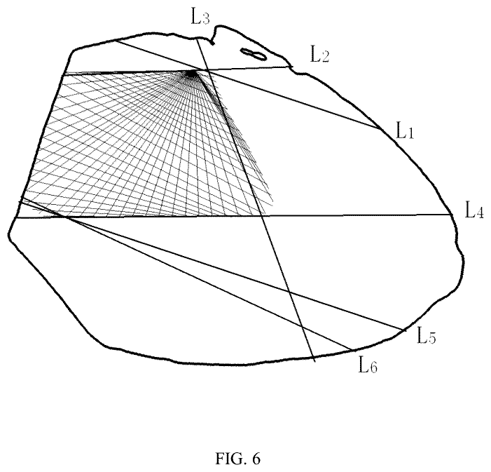

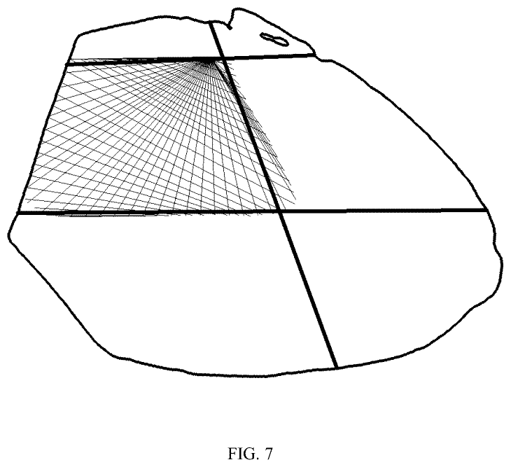

S2-7, rotating the single crystal image X₁ with the centroid center(x, y) of the contour “contour” determined in the S2-6 as a center, and obtaining a single crystal image Xᵢ (as shown in FIG. 4) every 5° of a rotation, wherein i is an integer greater than 1, and rotating by 360° in total, and repeating operations in the S2-2 to the S2-6 in each single crystal image Xᵢ to obtain all contours “contour” of each single crystal image Xᵢ;
S2-8, comparing the inscribed rectangular contour maxRect with the largest area among all the contours “contour” in each single crystal image Xᵢ, and determining an inscribed rectangle with a largest area in the single crystal region as MRect;
S3, dividing contour regions in the single crystal regions to find corresponding cutting lines;
S3-1, respectively extending one side of four sides of the inscribed rectangle MRect to an outside, and dividing the single crystal regions outside the inscribed rectangle MRect into four regions (as shown in FIG. 5) of Con₁, Con₂, Con₃ and Cor₄ by two extension lines at each vertex position of the inscribed rectangle MRect;
S3-2, selecting an intersection point of a vertex or the extension line of the inscribed rectangle MRect in Con₁ region and a contour of the single crystal region as P₁(x,y), forming a straight line with any point P₂(x,y) in the Con₁ region, circulating all points in the Con₁ region, calculating an area of a straight line formed by P₂(x,y) and P₁(x,y) cutting off heterocrystal regions, and sorting according to sizes of cutting off areas of the heterocrystal regions; selecting a group with a largest cutting off area of the heterocrystal regions as a candidate cutting line L₁; if areas of the heterocrystal regions cut off are the same, selecting a group with a largest area of a reserved single crystal region as the candidate cutting line L₁;
in Con₁, selecting an intersection point of an another vertex or extension line of the inscribed rectangle MRect and a contour of the single crystal region as P₃(x,y), forming a straight line with any point P₂(x,y) in the Con₁ region, and circulating all points in the Con₁ region, and calculating an area of a straight line formed by P₂(x,y) and P₃(x,y) cutting off heterocrystal regions, and determining the candidate cutting line L₂ in a same way as in the S3-2; sorting according to sizes of cutting off areas of the heterocrystal regions; selecting a group with a largest cutting off area of the heterocrystal regions as a candidate cutting line L₂; if areas of the heterocrystal regions cut off are the same, selecting a group with a largest area of a reserved single crystal region as the candidate cutting line L₂;
similarly, obtaining corresponding candidate cutting lines L₃, L₄, L₅ and L₆ in Con₂ region, Con₃ region and Cor₄ region respectively (as shown in FIG. 6).
S4, determining a final cutting line:
in order to ensure as few cutting lines as possible, path optimization is necessary. traversing six candidate cutting lines L₁, L₂, L₃, L₄, L₅ and L₆ determined in the S3, and selecting a path being capable of forming a convex polygon single crystal region with a largest area, a largest area of the heterocrystal region cut off and a least number of straight line cutting off as a final cutting line path (as shown in FIG. 7). The path optimization method is as follows:
setting an area of a divided single crystal pixel region to be Sₓ, A(⋅) represents an area of the single crystal region cut off and Z(⋅) represents an area of the heterocrystal region cut off:

$${r}_{opt 1} = ( {arg max}_{{r}_{e} , e ∈ Φ} ( {S}_{x} - A ( {arg max}_{{r}_{e} , e ∈ Φ} ( Z ( {r}_{e} {⋃}_{k = 1}^{p} {l}_{k} ) ) ) ) ) {\vert}_{min p} ; \qquad ( 3 )$$

$$Φ = [ 1 , {\sum }_{p = 1}^{m} {C}_{m}^{p} ] , {shape}_{e} is convex ; \qquad ( 4 )$$

where p represents a number of currently selected cutting lines; lₖ represents a selected k-th cutting line; m represents a total number of all candidate cutting lines, meaning a maximum number, Cm represents a number of permutation and combinations of selected p cutting lines among all m cutting lines; rₑ represents a planned path under a current e-th permutation and combination; shapeₑ represents a shape of a wafer cut by an e-th path; Φ represents a value range of e; rₒₚₜ₁ represents a currently selected optimal path, including selected p cutting lines.

The result of cutting line planning in this embodiment is shown in FIG. 7. By finding the largest inscribed rectangle in the contour of the single crystal region, the single crystal is divided into regions, and then cutting lines are planned in each region, so that there will be no redundant cutting lines, and cutting lines which are sufficient and not redundant may be planned.

The above describes only the specific embodiment of the present application, but the protection scope of the present application is not limited to this, and any change or substitution that may be easily thought of by a person familiar with the technical field within the technical scope disclosed by the present application should be included in the protection scope of the present application. Therefore, the protection scope of the present application should be based on the protection scope of the claims.

What is claimed is:

1. A cutting path planning algorithm for semiconductor workpiece based on image processing, comprising following steps:
S1, obtaining a semantic boundary of an image:
S1-1, obtaining a semantic image X through a deep learning model, and distinguishing different crystal phase regions in a wafer according to the semantic image X, wherein crystal phase regions to be reserved are single crystal regions, and a rest part are heterocrystal regions; setting the semantic image X as a gray scale map, wherein gray scale values of the single crystal regions are different from gray scale values of the heterocrystal regions;
S1-2, adjusting a color of the heterocrystal regions in the semantic image X obtained in S1-1 to be same as a background color to obtain a single crystal image X₁;
S2, finding a largest inscribed rectangle MRect in the single crystal image X1;
S2-1, finding all contours in the single crystal image X1, taking a contour with a largest area as a machining contour of a required product, and recording as contour “contour”, and then storing all contour points on the contour “contour” in sequence, and making a position difference between two adjacent contour points not greater than 1;
S2-2, randomly selecting a contour point on the contour “contour” and marking the contour point as start(x,y), circulating points in the contour “contour” with the start(x,y) as a starting point, marking a current point on the contour “contour” as cur(x,y), and taking the starting point start(x, y) and the current point cur(x,y) as diagonal points of the rectangle to construct a rectangular contour;
S2-3, judging whether the rectangular contour constructed in S2-2 are all located inside the contour “contour”, and if the rectangular contour constructed in S2-2 are all located inside the contour “contour”, recording an area of the rectangular contour and corresponding diagonal point coordinates in this state;
S2-4, repeatedly executing steps S2-2 to S2-3, traversing all points on the contour “contour” to obtain an inscribed rectangular contour maxRect with a largest area in the contour “contour”, and recording coordinates and an area of the inscribed rectangular contour maxRect with the largest area;
S2-5, calculating a space moment mⱼ; of the contour “contour” according a formula (1):
$${m}_{ji} = {\sum }_{x , y} ( ( x , y ) * {x}^{j} * {y}^{i} ) ; \qquad ( 1 )$$
in the formula (1), x and y are coordinate values of the contour “contour”, and i and j are image orders;
S2-6, when the image order i=0 or 1, and j=0 or 1, calculating a centroid center(x, y) of the contour “contour” from m₀₀, m₁₀ and m₀₁ obtained by a formula (2):
$$\{ \begin{matrix}x = \frac{{m}_{10}}{{m}_{00}} \\ y = \frac{{m}_{01}}{{m}_{00}}\end{matrix} ; \qquad ( 2 )$$
S2-7, rotating the single crystal image X₁ with the centroid center(x, y) of the contour “contour” determined in the S2-6 as a center, and obtaining a single crystal image Xᵢ every 5° of a rotation, wherein i is an integer greater than 1, and rotating by 360° in total, and repeating operations in the S2-2 to the S2-6 in each single crystal image Xᵢ to obtain all contours “contour” of each single crystal image Xᵢ;
S2-8, comparing the inscribed rectangular contour maxRect with the largest area among all the contours “contour” in each single crystal image Xᵢ, and determining an inscribed rectangle with a largest area in the single crystal region as MRect;
S3, dividing contour regions in the single crystal regions to find corresponding cutting lines;
S3-1, respectively extending one side of four sides of the inscribed rectangle MRect to an outside, and dividing the single crystal regions outside the inscribed rectangle MRect into four regions of Con₁, Con₂, Con₃ and Con₄ by two extension lines at each vertex position of the inscribed rectangle MRect;
S3-2, selecting an intersection point of a vertex or the extension line of the inscribed rectangle MRect in Con₁ region and a contour of the single crystal region as P₁(x,y), forming a straight line with any point P₂(x,y) in the Con₁ region, circulating all points in the Con₁ region, calculating an area of a straight line formed by P₂(x,y) and P₁(x,y) cutting off heterocrystal regions, and sorting according to sizes of cutting off areas of the heterocrystal regions; selecting a group with a largest cutting off area of the heterocrystal regions as a candidate cutting line L₁; if areas of the heterocrystal regions cut off are the same, selecting a group with a largest area of a reserved single crystal region as the candidate cutting line L₁;
in Con₁, selecting an intersection point of an another vertex or extension line of the inscribed rectangle MRect and a contour of the single crystal region as P₃(x,y), forming a straight line with any point P₂(x,y) in the Con₁ region, and circulating all points in the Con₁ region, and calculating an area of a straight line formed by P₂(x,y) and P₃(x,y) cutting off heterocrystal regions, and determining the candidate cutting line L₂ in a same way as in the S3-2;
similarly, obtaining corresponding candidate cutting lines L₃, L₄, L₅ and L₆ in Con₂ region, Con₃ region and Con₄ region respectively;
S4, determining a final cutting line:
traversing six candidate cutting lines L₁, L₂, L₃, L₄, L₅ and L₆ determined in the S3, and selecting a path being capable of forming a convex polygon single crystal region with a largest area, a largest area of the heterocrystal region cut off and a least number of straight line cutting off as a final cutting line path; a path optimization method is as follows:
setting an area of a divided single crystal pixel region to be Sₓ, A(⋅) represents an area of the single crystal region cut off and Z(⋅) represents an area of the heterocrystal region cut off:
$${r}_{opt 1} = ( {arg max}_{{r}_{e} , e ∈ Φ} ( {S}_{x} - A ( {arg max}_{{r}_{e} , e ∈ Φ} ( Z ( {r}_{e} {⋃}_{k = 1}^{p} {l}_{k} ) ) ) ) ) {\vert}_{min p} ; \qquad ( 3 )$$
$$Φ = [ 1 , {\sum }_{p = 1}^{m} {C}_{m}^{p} ] , {shape}_{e} is convex ; \qquad ( 4 )$$
wherein p represents a number of currently selected cutting lines; lₖ represents a selected k-th cutting line; m represents a total number of all candidate cutting lines, meaning a maximum number; Cₘ^{p} represents a number of permutation and combinations of selected p cutting lines among all m cutting lines; rₑ represents a planned path under a current e-th permutation and combination; shapeₑ represents a shape of a wafer cut by an e-th path; Φ represents a value range of e; rₒₚₜ₁ represents a currently selected optimal path, comprising selected p cutting lines.
